(19) United States
(12) Patent Application Publication
(10) Pub. No.: US 2019/0312501 A1
(43) Pub. Date: Oct. 10, 2019

(54) POWER SUPPLY CONTROL DEVICE

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventors: Kei Yamada, Yokkaichi, Mie (JP); Ken Furuto, Yokkaichi, Mie (JP)

(21) Appl. No.: 16/470,603

(22) PCT Filed: Dec. 12, 2017
(86) PCT No.: PCT/JP2017/044515

§ 371 Date: Jun. 18, 2019

(30) Foreign Application Priority Data
Dec. 20, 2016 (JP) 2016-247161

(51) Int. Cl. H02M 1/08; H02M 3/156; H03K 17/082

(52) U.S. Cl. CPC H02M 1/08; H03K 17/0822; H02M 3/156

(57) ABSTRACT

In a microcomputer provided in a power supply control device, an output circuit outputs a PWM signal, in the case where a control unit determines that the value of a switch current that flows via a semiconductor switch is less than a current threshold value. In the case where the control unit determines that the switch current value is equal to or greater than the current threshold value, the output circuit outputs a switch signal output by an output unit. The switch signal instructs ON or OFF of the semiconductor switch. A drive circuit switches the semiconductor switch to ON or OFF, based on the PWM signal or switch signal output by the output circuit.

### CROSS-REFERENCE TO RELATED APPLICATIONS

This application is the U.S. national stage of PCT/JP2017/044515 filed on Dec. 12, 2017, which claims priority of Japanese Patent Application No. JP 2016-247161 filed on Dec. 20, 2016, the contents of which are incorporated herein.

### TECHNICAL FIELD

The present disclosure relates to a power supply control device.

### BACKGROUND

JP 2011-72136A discloses a power supply control device that controls power supply from a power source to a load, by switching a semiconductor switch that is connected between the power source and the load to ON or OFF. With this power supply control device, in the case where the semiconductor switch is ON, current flows from the power source to the load, via the semiconductor switch, and power is supplied to the load. Also, power supply to the load stops, in the case where the semiconductor switch is OFF.

With the power supply control device described in JP 2011-72136A, in the case where the semiconductor switch is ON, it is determined whether the current value (hereinafter, switch current value) of current that flows via the semiconductor switch is equal to or greater than a current threshold value. In the case where it is determined that the switch current value is equal to or greater than the current threshold value, the semiconductor switch is switched to OFF. In the case where a predetermined time has elapsed from when the semiconductor switch is switched to OFF, the semiconductor switch is switched to ON, and it is again determined whether the switch current value is equal to or greater than the current threshold value.

In the case where it continues to be determined that the switch current value is equal to or greater than the current threshold value, the semiconductor switch is held at OFF. Current whose current value is equal to or greater than the current threshold value thereby does not continue to flow through the semiconductor switch for an extended time.

### SUMMARY

A power supply control device according to one aspect of the present disclosure includes a semiconductor switch, a switch signal output unit configured to output a switch signal instructing OFF or ON of the semiconductor switch, a determination unit configured to determine whether a value of a switch current that flows via the semiconductor switch is equal to or greater than a current threshold value, a signal output device configured to output a PWM signal, in a case where the determination unit determines that the switch current value is less than the current threshold value, and to output the switch signal output by the switch signal output unit, in a case where the determination unit determines that the switch current value is equal to or greater than the current threshold value, and a switching unit configured to switch the semiconductor switch to ON or OFF, based on the PWM signal or switch signal output by the signal output device.

### BRIEF DESCRIPTION OF DRAWINGS

FIG. 1 is a block diagram showing the configuration of a principal part of a power source system in a first embodiment.

FIG. 2 is a block diagram showing the configuration of a principal part of a microcomputer.

FIG. 3 is an illustrative diagram of operations of a control circuit and a timer signal.

FIG. 4 is an illustrative diagram of operations of an output circuit.

FIG. 5 is a flowchart showing a procedure of duty change processing.

FIG. 6 is a flowchart showing a procedure of switch protection processing.

FIG. 7 is an illustrative diagram of operations of a power supply control device.

FIG. 8 is another illustrative diagram of operations of the power supply control device.

FIG. 9 is a block diagram showing the configuration of a principal part of a microcomputer in a second embodiment.

FIG. 10 is an illustrative diagram of operations of an output circuit.

FIG. 11 is a flowchart showing a procedure of switch protection processing.

FIG. 12 is an illustrative diagram of operations of the power supply control device.

FIG. 13 is another illustrative diagram of operations of the power supply control device.

### DETAILED DESCRIPTION OF PREFERRED EMBODIMENTS

### Problems Solved by Present Disclosure

As a conventional power supply control device such as disclosed in JP 2011-72136A, a power supply control device provided with an output unit that outputs a PWM (Pulse Width Modulation) signal constituted by a high-level voltage value and a low-level voltage value is conceivable. This power supply control device supplies power to a load, by repeatedly switching the semiconductor switch to ON and OFF alternately, based on the PWM signal output by the output unit.

For example, the semiconductor switch is switched from OFF to ON in the case where the voltage value indicated by the PWM signal switches from the low-level voltage value to the high-level voltage value, and the semiconductor switch is switched from ON to OFF in the case where the voltage value indicated by the PWM signal switches from the high-level voltage value to the low-level voltage value.

A control unit that has a CPU (Central Processing Unit) instructs the output unit to change the duty of the PWM signal, and the output unit changes the duty of the PWM signal, in accordance with the instruction of the control unit. By changing the duty of the PWM signal, the time for which the semiconductor switch is ON in one cycle is changed, and thus power that is supplied to the load is changed. The duty is a value calculated by dividing the time, in one cycle, that the PWM signal indicates the high-level voltage value by one cycle. In the case where the duty is zero, the semiconductor switch is held at OFF, and, in the case where the duty is 1, the semiconductor switch is held at ON.

With a power supply control device that repeatedly switches the semiconductor switch to ON and OFF alternately, based on the PWM signal, the control unit holds the semiconductor switch at OFF, by controlling the output unit to change the duty of the PWM signal to zero, for example, in the case where it is determined that the switch current value is equal to or greater than a current threshold value. The control unit, in the case where a predetermined time has elapsed from when the output unit is instructed to change the duty to zero, controls the output unit to change the duty to a value exceeding zero, and resumes power supply to the load.

With the power supply control device constituted in this way, the timing at which the duty is changed to zero is a timing on or after the starting point in time of the cycle of the PWM signal that first arrives after the control unit instructs changing of the duty. Thus, there is a high possibility that the timing at which holding of the semiconductor switch at OFF is started will differ from the timing at which the control unit instructs changing of the duty.

Furthermore, the timing at which the duty is changed to a value exceeding zero is a timing on or after the starting point in time of the cycle of the PWM signal that first arrives after the abovementioned predetermined time has elapsed. Thus, there is a high possibility that the timing at which holding the semiconductor switch at OFF is released will differ from the timing at which the predetermined time has elapsed from when changing of the duty is instructed.

Given the above, there is a high possibility of a discrepancy arising between the time for which the semiconductor switch is held at OFF and the predetermined time.

In the case where the semiconductor switch is repeatedly held at OFF, for example, the temperature of the semiconductor switch increases each time the semiconductor switch is held at OFF for shorter than the predetermined time, and the semiconductor switch could possibly fail.

Also, in the case where the semiconductor switch is held at OFF for longer than the predetermined time, power supply to the load is stopped for a long time, thus resulting in the load being cooled for a long time.

With some loads that are installed in vehicles, the resistance value of the load is lower as the temperature decreases. In the case where power supply to such a load is controlled, an inrush current with a large current value flows to the load, immediately after power supply to the load is started. The temperature of the load increases due to the current flowing to the load. The value of current that flows to the load, that is, the switch current value, falls as the temperature of the load increases. Thereafter, inrush current does not flow to the load, as long as the temperature of the load does not fall to less than a given temperature. The initial determination related to the switch current value after power supply to the load is started is performed in a state where the temperature of the load is high.

However, in the case where it is determined that the switch current value is equal to or greater than the current threshold value, there is a possibility of the temperature of the load falling below the given temperature, when the semiconductor switch is switched to OFF for a long time. In this case, when the semiconductor switch has been switched to ON, the semiconductor switch could possibly be switched to OFF mistakenly, despite a normal current flowing to the load.

In view of this, an object of the present disclosure is to provide a power supply control device that is able to switch a semiconductor switch to ON or OFF, independently of the position of a starting point in time of the cycle of a PWM signal, in the case where it is determined that the value of current that flows via the semiconductor switch is equal to or greater than a current threshold value.

### Advantageous Effects of Present Disclosure

According to the present disclosure, a semiconductor switch can be switched to ON or OFF, independently of the position of a starting point in time of the cycle of a PWM signal, in the case where it is determined that the value of current that flows via the semiconductor switch is equal to or greater than a current threshold value.

Firstly, embodiments of the present disclosure will be listed and described. At least some of the embodiments described below may be suitably combined.

A power supply control device according to one aspect of the present disclosure includes a semiconductor switch, a switch signal output unit configured to output a switch signal instructing OFF or ON of the semiconductor switch, a determination unit configured to determine whether a value of a switch current that flows via the semiconductor switch is equal to or greater than a current threshold value, a signal output device configured to output a PWM signal, in a case where the determination unit determines that the switch current value is less than the current threshold value, and to output the switch signal output by the switch signal output unit, in a case where the determination unit determines that the switch current value is equal to or greater than the current threshold value, and a switching unit configured to switch the semiconductor switch to ON or OFF, based on the PWM signal or switch signal output by the signal output device.

In the above aspect, in the case where it is determined that the switch current value is less than the current threshold value, the signal output device outputs a PWM signal and the semiconductor switch switches to ON or OFF based on this PWM signal. In the case where it is determined that the switch current value is equal to or greater than the current threshold value, the signal output device outputs a switch signal and the semiconductor switch switches to ON or OFF based on this switch signal.

Thus, in the case where it is determined that the switch current value is equal to or greater than the current threshold value, it is possible, by switching the instruction of the switch signal, to switch the semiconductor switch to ON or OFF independently of the position of the starting point in time of the cycle of the PWM signal.

The power supply control device according to one aspect of the present disclosure, the signal output device outputs a switch signal instructing OFF of the semiconductor switch, in a case where the determination unit determines that the switch current value is equal to or greater than the current threshold value, and outputs a switch signal instructing ON of the semiconductor switch, in a case where a predetermined time has elapsed from when the determination unit determines that the switch current value is equal to or greater than the current threshold value, and the determination unit again determines whether the switch current value is equal to or greater than the current threshold value, after the signal output device outputs the switch signal instructing ON of the semiconductor switch.

In the above aspect, the semiconductor switch is held at OFF until the predetermined time elapses from when it is determined that the switch current value is equal to or greater than the current threshold value. Thereafter, the semiconductor switch is switched to ON and the determination related to the switch current value is performed again.

Here, in the case where it is determined that the switch current value is less than the current threshold value, the signal that is output by the signal output device switches from the switch signal to the PWM signal, assuming that the switch current value is an appropriate value. In the case where it is determined that the switch current value is equal to or greater than the current threshold value, the semiconductor switch is again held at OFF for a predetermined time, assuming that the switch current value is still not appropriate.

The power supply control device according to one aspect of the present disclosure, the switching unit fixes the semiconductor switch at OFF, in a case where the determination unit successively determines that the switch current value is equal to or greater than the current threshold value a predetermined number of times or more.

In the above aspect, in the case where it is determined that the switch current value is equal to or greater than the current threshold value successively for a predetermined number of times or more, the semiconductor switch is fixed at OFF, assuming that the switch current value will not return to an appropriate value.

In the power supply control device according to one aspect of the present disclosure, the switching unit switches the semiconductor switch to OFF independently of the signal being output by the signal output device, in a case where the switch current value becomes equal to or greater than a predetermined current value, and the current threshold value is less than the predetermined current value.

In the above aspect, in the case where the switch current value is equal to or greater than a predetermined current value that exceeds the current threshold value, such as a current value at which the semiconductor switch is likely to immediately fail, for example, the semiconductor switch is switched to OFF independently of the signal that is being output by the signal output device, and the semiconductor switch is protected.

### DETAILED DESCRIPTION OF EMBODIMENTS OF DISCLOSURE

Specific examples of a power supply control device according to embodiments of the present disclosure will be described below, with reference to the drawings. Note that the present disclosure is not limited to these illustrative examples, and all changes that come within the meaning and range of equivalency of the claims are intended to be encompassed therein.

### First Embodiment

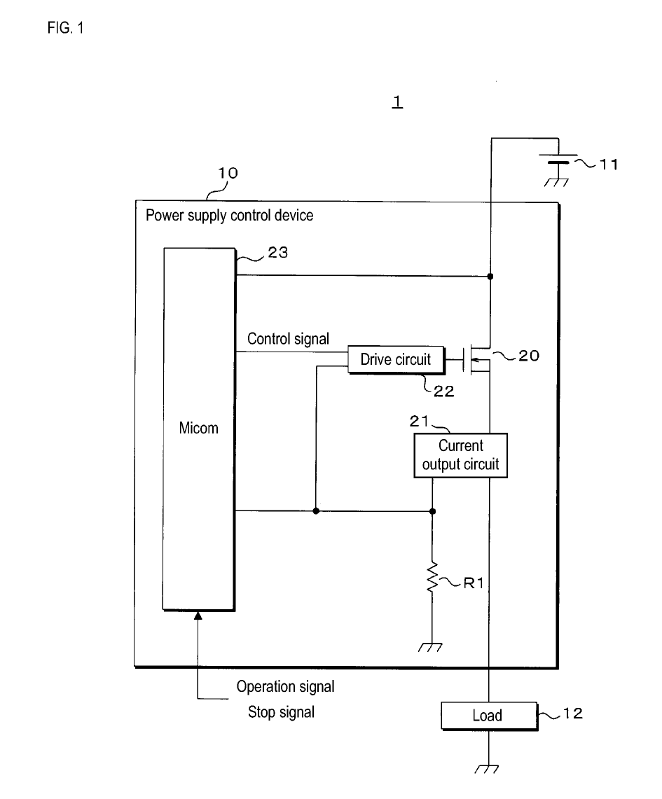

FIG. 1 is a block diagram showing the configuration of a principal part of a power source system 1 in the first embodiment. The power source system 1 is suitably installed in a vehicle, and is provided with a power supply control device 10, a battery 11, and a load 12. The power supply control device 10 is separately connected to an anode of the battery 11 and one end of the load 12. A cathode of the battery 11 and the other end of the load 12 are grounded.

The power supply control device 10 performs processing to connect the battery 11 and the load 12, and to interrupt this connection. In the case where the battery 11 and the load 12 are connected, power is supplied from the battery 11 to the load 12. In the case where connection of the battery 11 and the load 12 is interrupted, power supply from the battery 11 to the load 12 stops.

An operation signal that instructs operation of the load 12 and a stop signal that instructs stoppage of operation of the load 12 are input to the power supply control device 10. The power supply control device 10, in the case where the operation signal is input, repeatedly connects the battery 11 and the load 12 and interrupts this connection alternately. Power is thereby supplied to the load 12, and the load 12 operates. The power supply control device 10, in the case where the stop signal is input, continues to interrupt connection of the battery 11 and the load 12. Power supply to the load 12 thereby stops and the load 12 stops operation.

The power supply control device 10 has a semiconductor switch 20, a current output circuit 21, a drive circuit 22, a microcomputer (hereinafter, a micom) 23, and a resistor R1. The semiconductor switch 20 is an N-channel FET (Field Effect Transistor).

A drain of the semiconductor switch 20 is connected to the anode of the battery 11, and a source of the semiconductor switch 20 is connected to the current output circuit 21. The current output circuit 21 is further connected to one end of both the load 12 and the resistor R1. The other end of the resistor R1 is grounded. The one end of the resistor R1 is further connected to the drive circuit 22 and the micom 23. The drive circuit 22 is further connected to a gate of the semiconductor switch 20 and to the micom 23. The micom 23 is further connected to the drain of the semiconductor switch 20.

In the semiconductor switch 20, it is possible for current to flow via the drain and the source, in the case where the voltage value of the gate that is based on the potential of the source is equal to or greater than a given voltage value. At this time, the semiconductor switch 20 is ON.

Also, in the semiconductor switch 20, in the case where the voltage value of the gate that is based on the potential of the source is less than the given voltage value, current does not flow via the drain and the source. At this time, the semiconductor switch 20 is OFF.

In the case where the semiconductor switch 20 is switched to ON, the battery 11 and the load 12 are connected, current flows from the anode of the battery 11 via the semiconductor switch 20 and the current output circuit 21, and power is supplied from the battery 11 to the load 12. In the case where the semiconductor switch 20 is switched to OFF, connection of the battery 11 and the load 12 is interrupted, and power supply to the load 12 stops, without current flowing to the load 12.

The current output circuit 21 outputs, to the resistor R1, a current whose current value (hereinafter, switch current value) is a predetermined fraction of the current that flows via the semiconductor switch 20. The current output circuit 21 is constituted by a current mirror circuit, for example. In the case where the switch current value, the predetermined number and the resistance value of the resistor R1 are respectively denoted by Is, N and r1, the voltage value (hereinafter, end-to-end voltage value) Vd between both ends of the resistor R1 is represented by the following equation. The symbol “·” represents a multiplication operation.

Vd=(r1·Is)/N

Since the resistance value r1 and the predetermined number N are constants, the end-to-end voltage value Vd is proportional to the switch current value Is.

The end-to-end voltage value of the resistor R1 is input to the drive circuit 22. The micom 23 outputs a control signal constituted by a high-level voltage value and a low-level voltage value to the drive circuit 22.

The drive circuit 22, in the case where the end-to-end voltage value is less than a reference voltage value Vr, increases the voltage value of the gate of the semiconductor switch 20 that is based on the ground potential, when the voltage value indicated by the control signal switches from the low-level voltage value to the high-level voltage value. In the semiconductor switch 20, the voltage of the gate that is based on the potential of the source thereby increases, and the semiconductor switch 20 switches from OFF to ON. The reference voltage value Vr is constant and is set in advance.

The drive circuit 22, in the case where the end-to-end voltage value is less than the reference voltage value Vr, reduces the voltage value of the gate of the semiconductor switch 20 that is based on the ground potential, when the voltage value indicated by the control signal switches from the high-level voltage value to the low-level voltage value. In the semiconductor switch 20, the voltage of the gate that is based on the potential of the source thereby falls, and the semiconductor switch 20 switches from ON to OFF.

The drive circuit 22, in the case where the end-to-end voltage value becomes equal to or greater than the reference voltage value Vr, reduces the voltage value of the gate of the semiconductor switch 20 that is based on the ground potential and switches the semiconductor switch 20 to OFF, independently of the voltage value indicated by the control signal. Thereafter, the drive circuit 22 fixes the semiconductor switch 20 at OFF independently of the end-to-end voltage value.

The switch current value in the case where the end-to-end voltage value is the reference voltage value is denoted as a reference current value. The reference current value is represented by (N·Vr)/r1. The end-to-end voltage value being equal to or greater than the reference voltage value corresponds to the switch current value being equal to or greater than the reference current value, and the end-to-end voltage value being less than the reference voltage corresponds to the switch current value being less than the reference current value. Since the predetermined number N, the reference voltage value Vr and the resistance value r1 are each constant, the reference current value is also constant.

The operation signal or the stop signal is input to the micom 23. Furthermore, the voltage value (hereinafter, battery voltage value) between both ends of the battery 11 is input to the micom 23. The micom 23 performs adjustment related to the control signal, based on the input signal and the battery voltage value.

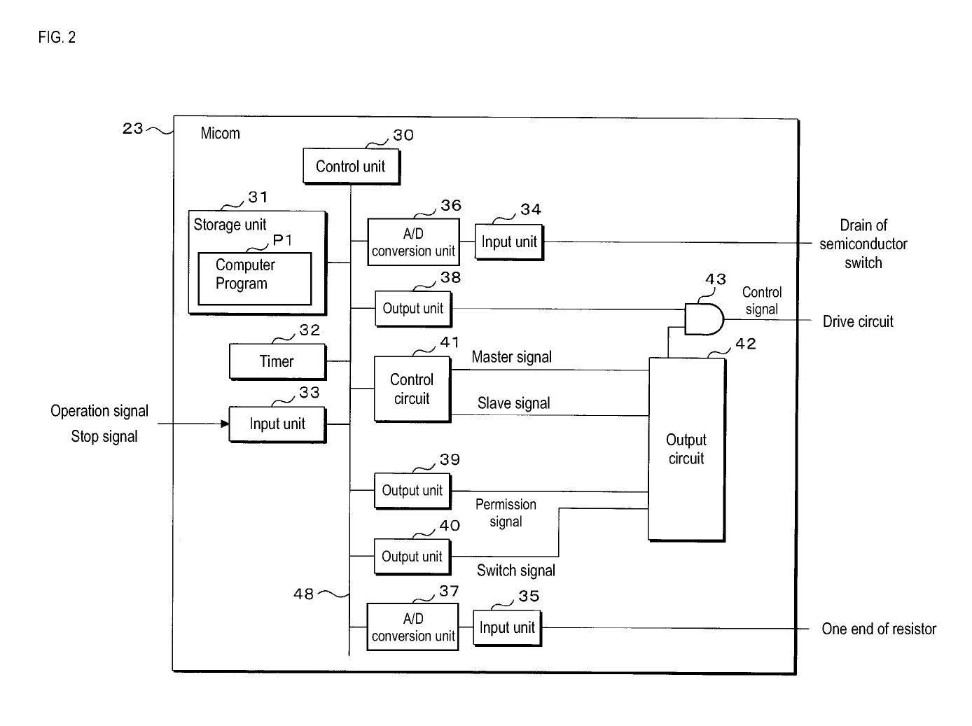

FIG. 2 is a block diagram showing the configuration of a principal part of the micom 23. The micom 23 has a control unit 30, a storage unit 31, a timer 32, input units 33, 34 and 35, A/D (Analog-to-Digital) conversion units 36 and 37, output units 38, 39 and 40, a control circuit 41, an output circuit 42, and an AND circuit 43. The AND circuit 43 has two input ends and one output end.

The control unit 30, the storage unit 31, the timer 32, the input unit 33, the A/D conversion units 36 and 37, the output units 38, 39 and 40 and the control circuit 41 are separately connected to a bus 48. The A/D conversion unit 36 is connected to the input unit 34 apart from the bus 48. The input unit 34 is further connected to the drain of the semiconductor switch 20. The A/D conversion unit 37 is connected to the input unit 35 apart from the bus 48. The input unit 35 is further connected to one end of the resistor R1.

The output units 39 and 40 and the control circuit 41 are separately connected to the output circuit 42, apart from the bus 48. The output unit 38 is connected to one of the input ends of the AND circuit 43, apart from the bus 48. The output circuit 42 is further connected to the other input end of the AND circuit 43.

The timer 32 starts and ends clocking of time, in accordance with instructions of the control unit 30. The clocked time that is clocked by the timer 32 is read out by the control unit 30.

The operation signal and the stop signal are input to the input unit 33. The input unit 33, in the case where the operation signal or the stop signal is input, notifies the input signal to the control unit 30.

An analog battery voltage value is input to the input unit 34. The input unit 34, in the case where the analog battery voltage value is input, outputs the input analog battery voltage value to the A/D conversion unit 36. The A/D conversion unit 36 converts the analog battery voltage value input from the input unit 34 to a digital battery voltage value. The control unit 30 acquires the digital battery voltage value from the A/D conversion unit 36. The battery voltage value that the control unit 30 acquires from the A/D conversion unit 36 substantially matches the battery voltage value at the point in time of acquisition.

Similarly, an analog end-to-end voltage value of the resistor R1 is input to the input unit 35. The input unit 35, in the case where the analog end-to-end voltage value is input, outputs the input analog end-to-end voltage value to the A/D conversion unit 37. The A/D conversion unit 37 converts the analog end-to-end voltage value input from the input unit 35 to a digital end-to-end voltage value. The control unit 30 acquires the digital end-to-end voltage value from the A/D conversion unit 37. The end-to-end voltage value that the control unit 30 acquires from the A/D conversion unit 37 substantially matches the end-to-end voltage value at the point in time of acquisition.

The output unit 38 outputs the high-level voltage value or the low-level voltage value to one of the input ends of the AND circuit 43. The output unit 38 changes the voltage value being output to the high-level voltage value or the low-level voltage value, in accordance with instructions of the control unit 30. The output circuit 42 outputs a signal constituted by a high-level voltage value and a low-level voltage value to the other input end of the AND circuit 43.

The AND circuit 43, in the case where the output unit 38 is outputting the high-level voltage value, outputs the signal being output by the output circuit 42 to the drive circuit 22 as the control signal. In this case, when the switch current value is less than the reference current value, the drive circuit 22 switches the semiconductor switch 20 to ON or OFF based on the voltage value indicated by the signal being output by the output circuit 42.

The AND circuit 43, in the case where the output unit 38 is outputting the low-level voltage value, outputs a control signal indicating the low-level voltage value to the drive circuit 22, independently of the signal being output by the output circuit 42. In this case, the drive circuit 22 holds the semiconductor switch 20 at OFF.

The control circuit 41 outputs both a master signal and a slave signal to the output circuit 42. The master signal and the slave signal are each constituted by a high-level voltage and a low-level voltage. The master counter value and the slave counter value are stored in the control circuit 41. A master counter value and a slave counter value are each decremented by 1, whenever a fixed time elapses. The fixed time related to the master counter value and the slave counter value is the same. The master signal is based on the master counter value, the slave signal is based on the slave counter value. The output circuit 42 generates a timer signal based on the master signal and slave signal output by the control circuit 41.

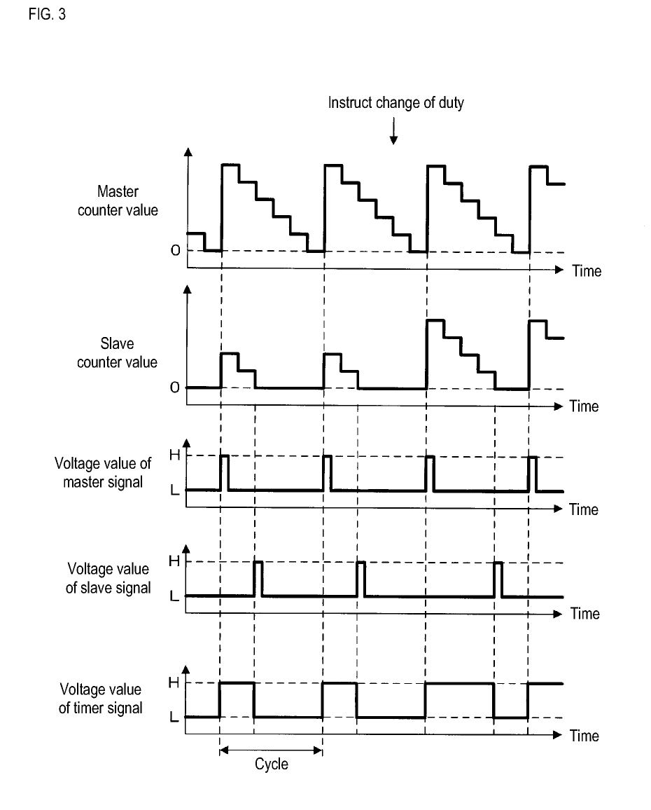

FIG. 3 is an illustrative diagram of operations of the control circuit 41 and the timer signal. Transition of both the master counter value and the slave counter value and transition of the voltage values respectively indicated by the master signal, the slave signal and the timer signal are shown in FIG. 3. In FIG. 3, “H” indicates the high-level voltage value and “L” indicates the low-level voltage value. Time is shown on the horizontal axis.

The master counter value decreases by 1, whenever the fixed time elapses. In the case where the master counter value reaches zero, the master counter value is changed to a first integer value after the fixed time has elapsed. The first integer value is an integer value exceeding zero. Thereafter, the master counter value again decreases by 1, whenever the fixed time elapses. In the example of FIG. 3, the first integer value is 5.

The slave counter value also decreases by 1, whenever the fixed time elapses, similarly to the master counter value. In the case where the slave counter value reaches zero, the slave counter value is maintained at zero until the master counter value is changed from zero to the first integer value. In the case where the master counter value is changed from zero to the first integer value, the slave counter value is changed from zero to a second integer value, and again decreases by 1, whenever the fixed time elapses. The second integer value is an integer value that is equal to or greater than zero and equal to or less than the first integer value.

The voltage value indicated by the master signal switches from the low-level voltage value to the high-level voltage value, whenever the master counter value is changed from zero to the first integer value. The voltage value indicated by the master signal returns to the low-level voltage value immediately after switching to the high-level voltage value. The master counter value is changed from zero to the first integer value, whenever a time that is represented by the product of the first integer value and the aforementioned fixed time elapses, and the first integer value is fixed. Thus, the voltage value indicated by the master signal periodically switches from the low-level voltage value to the high-level voltage value.

The voltage value indicated by the slave signal switches from the low-level voltage value to the high-level voltage value, whenever the slave counter value reaches zero. The voltage value indicated by the slave signal returns to the low-level voltage value immediately after switching to the high-level voltage value. The slave counter value is changed from zero to the second integer value, whenever a time that is represented by the product of the second integer value and the aforementioned fixed time elapses. The second integer value is changed in a range from zero or greater to the first integer value or less. Thus, in the case where the second integer value is changed, the time interval for the slave signal to switch from the low-level voltage value to the high-level voltage value is changed.

The voltage value indicated by the timer signal switches from the low-level voltage value to the high-level voltage value, in the case where the voltage value indicated by the master signal switches from the low-level voltage value to the high-level voltage value, and switches from the high-level voltage value to the low-level voltage value, in the case where the voltage value indicated by the slave signal switches from the low-level voltage value to the high-level voltage value. As mentioned above, the voltage value indicated by the master signal periodically switches from the low-level voltage value to the high-level voltage value. Thus, the voltage value indicated by the timer signal also periodically switches from the low-level voltage value to the high-level voltage value. The time for which the timer signal indicates the high-level voltage value is represented by the product of the second integer value and the aforementioned fixed time, and is longer as the second integer value increases. The duty of the timer signal is a value calculated by dividing the time, in one cycle, that the timer signal indicates the high-level voltage value by one cycle. The duty of the timer signal is larger as the second integer value increases. The timer signal is a PWM signal.

The control unit 30 instructs the control circuit 41 to change the second integer value. The duty of the timer signal is thereby changed. The duty of the timer signal is calculated by (second integer value)/((first integer value)+1). In the example of FIG. 3, the duty is 0.33 (=2/(5+1)) in the case where the second integer value is 2, and the duty is 0.66 (=4/(5+1)) in the case where the second integer value is 4. In the case where the control unit 30 instructs the control circuit 41 to change the duty of the timer signal, the duty of the timer signal is changed on or after the point in time at which the cycle first arrives after changing of the duty was instructed. The control circuit 41, in the case where the master counter value is changed from zero to the first integer value, notifies this change to the control unit 30.

The output unit 39 shown in FIG. 2 outputs a permission signal constituted by a high-level voltage value and a low-level voltage value to the output circuit 42. The control unit 30 instructs the output unit 39 to switch the voltage value indicated by the permission signal to the high-level voltage value or the low-level voltage value.

The output unit 40 outputs a switch signal constituted by a high-level voltage value and a low-level voltage value to the output circuit 42. The control unit 30 instructs the output unit 40 to change the voltage value indicated by the switch signal to the high-level voltage value or the low-level voltage value.

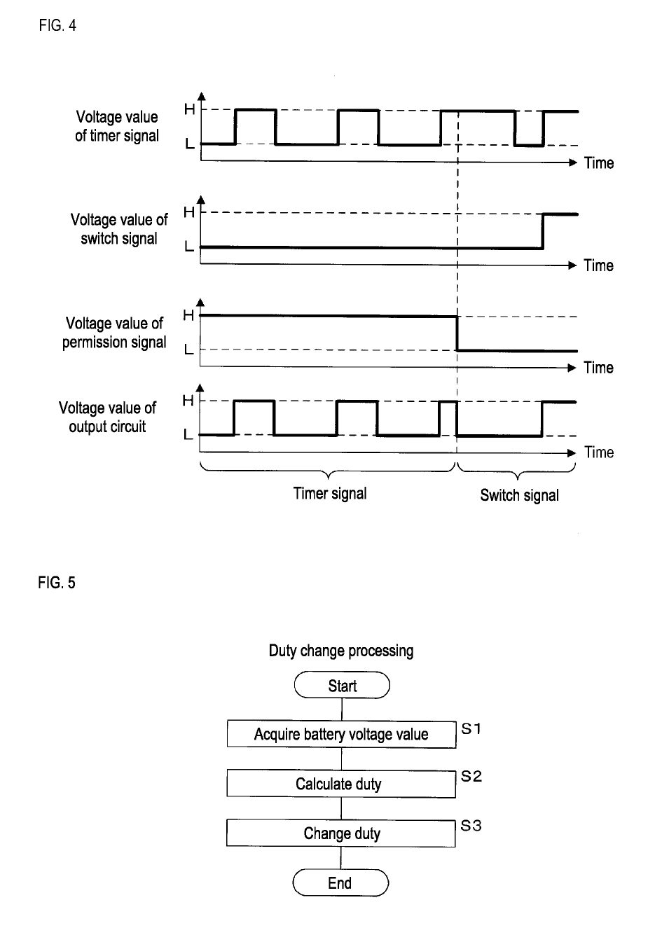

FIG. 4 is an illustrative diagram of operations of the output circuit 42. Transition of the voltage values respectively indicated by the timer signal, the switch signal and the permission signal and transition of the voltage value that the output circuit 42 outputs to the AND circuit 43 are shown in FIG. 4. In FIG. 4 also, “H” indicates the high-level voltage value and “L” indicates the low-level voltage value. Time is shown on the horizontal axis.

The output circuit 42, in the case where the permission signal indicates the high-level voltage value, generates a timer signal, based on the master signal and slave signal input from the control circuit 41, and outputs the generated timer signal to the AND circuit 43. The output circuit 42, in the case where the permission signal indicates the low-level voltage value, outputs the switch signal input from the output unit 40 to the AND circuit 43.

Note that, in FIG. 4, the voltage value of the timer signal in the period during which the permission signal indicates the low-level voltage value is the voltage value of the timer signal that is generated in the case where the permission signal is assumed to be indicating the high-level voltage value. In actuality, as aforementioned, in the case where the permission signal indicates the low-level voltage value, the output circuit 42 does not generate the timer signal.

The permission signal indicates whether to permit the output circuit 42 to output the timer signal to the AND circuit 43. The permission signal indicating the high-level voltage value corresponds to output of the timer signal being permitted, and the permission signal indicating the low-level voltage value corresponds to output of the timer signal not being permitted.

In the case where the output unit 38 is outputting the high-level voltage value, the AND circuit 43 outputs the timer signal or switch signal input from the output circuit 42 to the drive circuit 22 as the control signal.

In the case where the end-to-end voltage value of the resistor R1 is less than the reference voltage value, the drive circuit 22 switches the semiconductor switch 20 to ON or OFF based on the voltage value indicated by the timer signal, when the AND circuit 43 is outputting the timer signal as the control signal. Accordingly, the drive circuit 22 switches the semiconductor switch 20 from OFF to ON, in the case where the voltage value indicated by the timer signal switches from the low-level voltage value to the high-level voltage value, and switches the semiconductor switch 20 from ON to OFF, in the case where the voltage value indicated by the timer signal switches from the high-level voltage value to the low-level voltage value.

In the case where the end-to-end voltage value of the resistor R1 is less than the reference voltage value, the drive circuit 22 switches the semiconductor switch 20 to ON or OFF based on the voltage value indicated by the switch signal, when the AND circuit 43 is outputting the switch signal as the control signal. Accordingly, the drive circuit 22 switches the semiconductor switch 20 from OFF to ON, in the case where the voltage value indicated by the switch signal switches from the low-level voltage value to the high-level voltage value, and switches the semiconductor switch 20 from ON to OFF, in the case where the voltage value indicated by the switch signal switches from the high-level voltage value to the low-level voltage value.

Accordingly, the switch signal is a signal that instructs ON or OFF of the semiconductor switch 20. The switch signal indicating the high-level voltage value corresponds to instructing ON of the semiconductor switch 20, and the switch signal indicating the low-level voltage value corresponds to instructing OFF of the semiconductor switch 20. The output unit 40 functions as the switch signal output unit.

The storage unit 31 is a nonvolatile memory, for example. A computer program P1 is stored in the storage unit 31. The control unit 30 has a CPU which is not illustrated. The CPU of the control unit 30 executes power supply start processing, power supply end processing, duty change processing, and switch protection processing, by executing the computer program P1. The power supply start processing is processing for starting power supply to the load 12. The power supply end processing is processing for ending power supply to the load 12. The duty change processing is processing for changing the duty of the timer signal. The switch protection processing is processing for protecting the semiconductor switch 20.

The control unit 30 executes the power supply start processing, in the case where the operation signal is input to the input unit 33. In the power supply start processing, the control unit 30 controls the output unit 38 to output the high-level voltage value, and instructs the output unit 39 to switch the voltage value indicated by the permission signal to the high-level voltage value. The output circuit 42 thereby outputs the timer signal, and the AND circuit 43 outputs the timer signal to the drive circuit 22 as the control signal. Switching of the semiconductor switch 20 to ON and OFF is thereby repeated alternately, based on the voltage value indicated by the timer signal. As a result, power supply to the load 12 is started, and the load 12 operates.

The control unit 30, in the case of starting power supply to the load 12, instructs the control circuit 41 to gradually increase the duty of the timer signal from zero. The time for which the semiconductor switch 20 is ON thereby gradually increases. Thus, for example, even if the load 12 is a load whose resistance value is smaller as the temperature decreases, the switch current value will not become equal to or greater than a current threshold value described later. The control unit 30 ends the power supply start processing in the case where the duty of the timer signal reaches a predetermined value, for example.

The control unit 30 executes the power supply end processing, in the case where the stop signal is input to the input unit 33. In the power supply end processing, the control unit 30 controls the output unit 38 to output the low-level voltage value. The AND circuit 43 thereby continues to output the control signal indicating the low-level voltage value, and the drive circuit 22 holds the semiconductor switch 20 at OFF. As a result, power supply to the load 12 stop described later 12 stops operation. The control unit 30 ends the power supply end processing, after controlling the output unit 38 to output the low-level voltage value.

FIG. 5 is a flowchart showing a procedure of the duty change processing. The control unit 30 periodically executes the duty change processing between executing the power supply start processing and executing the power supply end processing. In the duty change processing, the control unit 30, first, acquires the battery voltage value from the A/D conversion unit 36 (step S1), and calculates the duty based on the acquired battery voltage value (step S2). Next, the control unit 30 instructs the control circuit 41 to change the duty of the timer signal to the duty calculated in step S2 (step S3). Specifically, the control unit 30 instructs the control circuit 41 to change the second integer value to an integer value corresponding to the duty calculated in step S2.

For example, in the case where the load 12 is a light bulb, the control unit 30, in step S2, calculates a duty D, using the following equation represented by a battery voltage value Vb and a setting voltage value Vs set in advance. The setting voltage value Vs is a given voltage value that is less than the battery voltage value Vb.

D=(Vs/Vb)²

In the case where the duty D is calculated with this equation, the power that is consumed by the light bulb is maintained at a constant power, even when the battery voltage value Vb varies. The intensity of light that the light bulb emits is dependent on the power that is consumed by the light bulb. Accordingly, in the case where the power that is consumed by the light bulb is maintained at a constant power, the intensity of light that the light bulb emits is also maintained at a constant intensity.

For example, in the case where the load 12 is a light emitting diode, the control unit 30, in step S2, calculates the duty D, using the following equation represented by the battery voltage value Vb, the setting voltage value Vs, and a forward voltage value Ve of the light emitting diode. The forward voltage value Ve is the magnitude of the voltage drop that occurs in the light emitting diode in the case where current flows in the forward direction of the light emitting diode.

D=(Vs−Ve)/(Vb−Ve)

In the case where the duty D is calculated with this equation, the value of current that flows through the light emitting diode is maintained at a constant current value, even when the battery voltage value Vb varies. The intensity of light that the light emitting diode emits is dependent on the value of current that flows through the light emitting diode. Accordingly, in the case where the value of current that flows through the light emitting diode is maintained at a constant current value, the intensity of light that the light emitting diode emits is also maintained at a constant intensity.

The control unit 30 ends the duty change processing, after executing step S3.

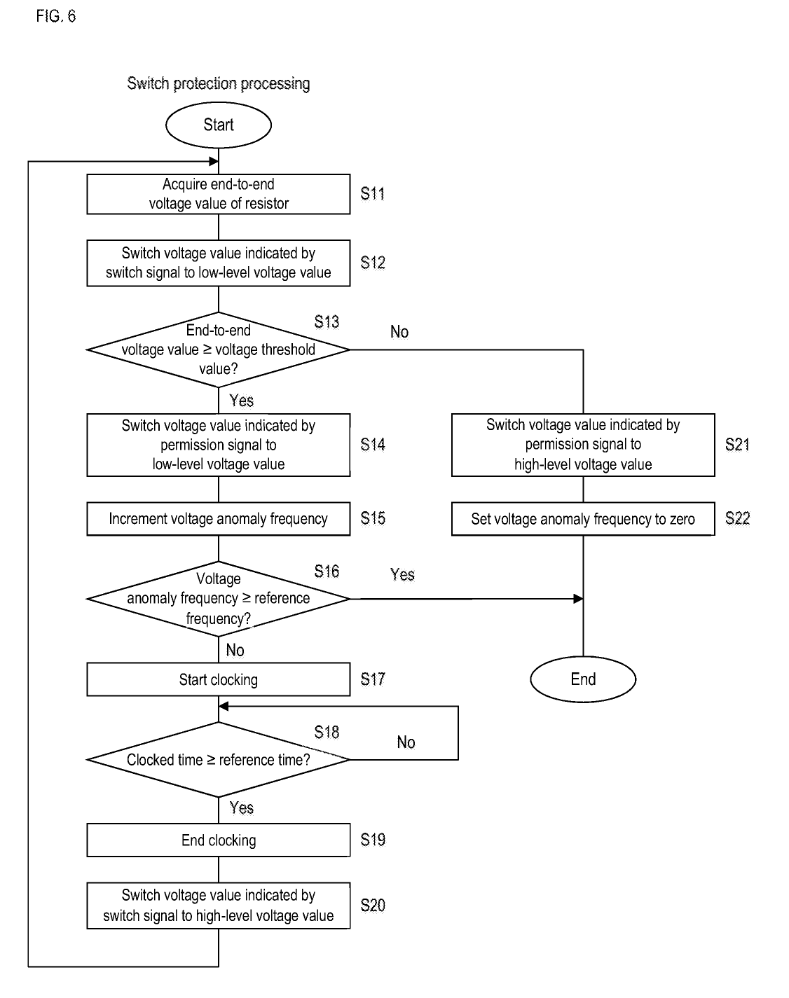

FIG. 6 is a flowchart showing a procedure of the switch protection processing. The control unit 30, in the case where the control circuit 41 notifies that the master counter value was changed from zero to the first integer value between the power supply start processing ending and the power supply end processing starting, executes the switch protection processing when the permission signal is indicating the high-level voltage value. Because the master counter value is periodically changed from zero to the first integer value, the switch protection processing is periodically executed, in the case where the permission signal is the high-level voltage value. Because the permission signal indicates the high-level voltage value at the point in time at which the switch protection processing is started, the output circuit 42 outputs the timer signal to the AND circuit 43.

In the switch protection processing, the control unit 30 acquires the end-to-end voltage value of the resistor R1 (step S11) from the A/D conversion unit 37, and instructs the output unit 40 to switch the voltage value indicated by the switch signal to the low-level voltage value (step S12). Next, the control unit 30 determines whether the end-to-end voltage value acquired in step S11 is equal to or greater than the voltage threshold value (step S13). The voltage threshold value is a given voltage value set in advance, and is less than the reference voltage value.

The switch current value in the case where the end-to-end voltage value is the voltage threshold value is described as the current threshold value. The current threshold value is represented by (N·Vth)/r1. Here, Vth is the voltage threshold value. N and r1 are respectively the predetermined number and the resistance value of the resistor R1, as mentioned above. The end-to-end voltage value being less than the voltage threshold value corresponds to the switch current value being less than the current threshold value, and the end-to-end voltage value being equal to or greater than the voltage threshold value corresponds to the switch current value being equal to or greater than the current threshold value. Executing step S13 corresponds to determining whether the switch current value is equal to or greater than the current threshold value. The control unit 30 functions as the determination unit.

Also, the voltage threshold value is less than the reference voltage value. Thus, the current threshold value is less than the reference current value. Since the predetermined number N, the voltage threshold value Vth and the resistance value r1 are each constant, the current threshold value is also constant.

The control unit 30, in the case where it is determined that the end-to-end voltage value is equal to or greater than the voltage threshold value, that is, that the switch current value is equal to or greater than the current threshold value (S13: YES), instructs the output unit 39 to switch the voltage value indicated by the permission signal to the low-level voltage value (step S14). The output circuit 42 thereby outputs the switch signal output by the output unit 40 to the AND circuit 43, and the AND circuit 43 outputs the switch signal to the drive circuit 22 as the control signal. The drive circuit 22 switches the semiconductor switch 20 to ON or OFF based on the voltage value indicated by the switch signal output by the output circuit 42.

At the point in time that step S14 is executed, the switch signal indicates the low-level voltage value. Thus, the output circuit 42, in the case where the control unit 30 determines in step S13 that the switch current value is equal to or greater than the current threshold value, outputs a switch signal indicating the low-level voltage value, that is, a switch signal instructing OFF of the semiconductor switch 20, to the AND circuit 43. Since the output unit 38 is outputting the high-level voltage value, the AND circuit 43 outputs the switch signal instructing OFF of the semiconductor switch 20 to the drive circuit 22, and the drive circuit 22 switches the semiconductor switch 20 to OFF.

The control unit 30, after executing step S14, increments a voltage anomaly frequency by 1 (step S15). The voltage anomaly frequency is the number of times that the control unit 30 successively determines that the end-to-end voltage value is equal to or greater than the voltage threshold value in step S13, and is stored in the storage unit 31.

Next, the control unit 30 determines whether the voltage anomaly frequency is equal to or greater than a reference frequency (step S16). The reference frequency is an integer value of two or more, and is set in advance. The control unit 30, in the case where it is determined that the voltage anomaly frequency is less than the reference frequency (S16: NO), controls the timer 32 to start clocking time (step S17), and it is determined whether the clocked time clocked by the timer 32 is equal to or greater than a reference time (step S18). The reference time is constant, and is set in advance. The control unit 30, in the case where it is determined that the clocked time is less than the reference time (S18: NO), executes step S18 again, and waits until the clocked time becomes equal to or greater than the reference time.

The control unit 30, in the case where it is determined that the clocked time is equal to or greater than the reference time (S18: YES), controls the timer 32 to end the clocking (step S19), and instructs the output unit 40 to switch the voltage value indicated by the switch signal to the high-level voltage value (step S20). The drive circuit 22 thereby switches the semiconductor switch 20 to ON.

As described above, the output circuit 42 outputs a switch signal instructing ON of the semiconductor switch 20, in the case where the reference time has elapsed from when the control unit 30 determines that the switch current value is equal to or greater than the current threshold value in step S13.

The control unit 30, after executing step S20, executes step S11 again in a state where the switch signal indicates the high-level voltage value, that is, a state where the drive circuit 22 is keeping the semiconductor switch 20 switched to ON. Thereafter, the control unit 30 sequentially executes steps S12 and S13. Accordingly, the control unit 30 again determines whether the switch current value is equal to or greater than the current threshold value in step S13, after the output circuit 42 outputs the switch signal instructing ON of the semiconductor switch 20.

The control unit 30, in the case where it is determined that the end-to-end voltage value of the resistor R1 is less than the voltage threshold value, that is, that the switch current value is less than the current threshold value (S13: NO), instructs the output unit 39 to switch the voltage value indicated by the permission signal to the high-level voltage value (step S21). The output circuit 42 thereby outputs the timer signal output by the control circuit 41 to the AND circuit 43, and the AND circuit 43 outputs the timer signal to the drive circuit 22 as the control signal. The drive circuit 22 switches the semiconductor switch 20 to ON or OFF based on the voltage value indicated by the timer signal output by the output circuit 42. The output circuit 42 functions as the signal output device, and the drive circuit 22 functions as the switching unit.

The control unit 30, after executing step S21, sets the voltage anomaly frequency to zero (step S22), and ends the switch protection processing. In the case where step S22 is executed and the switch protection processing is ended, the control unit 30 executes the switch protection processing again, when it is notified that the master counter value was changed from zero to the first integer value.

The control unit 30, in the case where it is determined that the voltage anomaly frequency is equal to or greater than the reference frequency (S16: YES), ends the switch protection processing. In this case, the switch protection processing is ended in a state where the permission signal and the switch signal indicate the low-level voltage value, that is, a state where the drive circuit 22 is keeping the semiconductor switch 20 switched to OFF. In the case where it is determined that the voltage anomaly frequency is equal to or greater than the reference frequency in step S16 and the switch protection processing is ended, the control unit 30 does not execute the switch protection processing, even when it is notified that the master counter value was changed from zero to the first integer value. Thus, OFF of the semiconductor switch 20 is fixed.

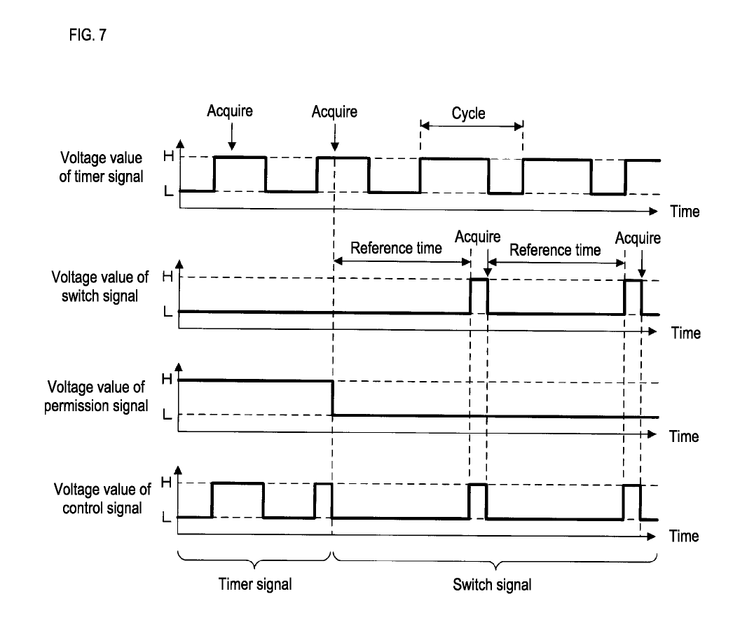

FIG. 7 is an illustrative diagram of operations of the power supply control device 10. Transition of the voltage values respectively indicated by the timer signal, the switch signal, the permission signal and the control signal is shown in FIG. 7. In FIG. 7 also, “H” indicates the high-level voltage value and “L” indicates the low-level voltage value. Time is shown on the horizontal axis.

Note that, in FIG. 7, similarly to FIG. 4, the voltage value of the timer signal in the period during which the permission signal indicates the low-level voltage value is the voltage value of a timer signal that is generated in the case where the permission signal is assumed to indicate the high-level voltage value.

Hereinafter, it is assumed that the switch current value is less than the reference current value, and the output unit 38 outputs the high-level voltage value. As aforementioned above, the output unit 38 outputs the high-level voltage value from when the operation signal is input to the input unit 33 until when the stop signal is input to the input unit 33.

In the case where the permission signal indicates the high-level voltage value, the output circuit 42 outputs a timer signal generated based on the master signal and the slave signal to the AND circuit 43, and the AND circuit 43 outputs the timer signal to the drive circuit 22 as the control signal. Thus, the drive circuit 22 repeatedly switches the semiconductor switch 20 to ON and OFF alternately, based on the voltage value indicated by the timer signal.

As described above, in the case where the master counter value is changed from zero to the first integer value, the voltage value indicated by the timer signal switches from the low-level voltage value to the high-level voltage value. At this time, the control circuit 41 notifies the control unit 30 that the master counter value was changed from zero to the first integer value, and the switch protection processing is started. In the switch protection processing, the control unit 30 acquires the end-to-end voltage value of the resistor R1 from the A/D conversion unit 37, and determines whether the end-to-end voltage value is equal to or greater than the voltage threshold value. The time from when the switch protection processing is started until when the end-to-end voltage value is acquired is shorter than the minimum ON time capable of being adjusted to with the timer signal. In the case where the permission signal indicates the high-level voltage value, the switch signal indicates the low-level voltage value.

The control unit 30, in the case where it is determined that the end-to-end voltage value of the resistor R1 is less than the voltage threshold value, ends the switch protection processing in a state where the voltage values indicated by the switch signal and the permission signal are respectively maintained at the low-level voltage value and the high-level voltage value. Thereafter, in the case where the voltage value indicated by the timer signal switches from the low-level voltage value to the high-level voltage value, the control unit 30 again starts the switch protection processing, acquires the end-to-end voltage value, and determines whether the end-to-end voltage value is equal to or greater than the voltage threshold value.

The control unit 30 switches the voltage value indicated by the permission signal to the low-level voltage value, in the case where it is determined that the end-to-end voltage value of the resistor R1 is equal to or greater than the voltage threshold value. The output circuit 42 thereby outputs the switch signal to the AND circuit 43, and the AND circuit 43 outputs the switch signal as the control signal. At this time, the switch signal is indicating the low-level voltage value, and thus, in the case where the control unit 30 determines that the end-to-end voltage value is equal to or greater than the voltage threshold value, the voltage value indicated by the control signal immediately switches to the low-level voltage value, and the drive circuit 22 switches the semiconductor switch 20 to OFF.

The control unit 30, in the case where the reference time has elapsed from when it is determined that the end-to-end voltage value is equal to or greater than the voltage threshold value, instructs the output unit 40 to switch the voltage value indicated by the switch signal from the low-level voltage value to the high-level voltage value. The drive circuit 22 thereby switches the semiconductor switch 20 to ON. Thereafter, the control unit 30 acquires the end-to-end voltage value of the resistor R1 from the A/D conversion unit 37, and instructs the output unit 40 to return the voltage value indicated by the switch signal from the high-level voltage value to the low-level voltage value. The control unit 30 again determines whether the end-to-end voltage value of the resistor R1 is equal to or greater than the voltage threshold value.

The control unit 30, in the case where it is determined that the end-to-end voltage value of the resistor R1 is equal to or greater than the voltage threshold value, that is, that the switch current value is equal to or greater than the current threshold value, the drive circuit 22 holds OFF of the semiconductor switch 20 for the reference time, assuming that the switch current value is still not appropriate. The control unit 30, in the case where the reference time has elapsed from when it is determined that the end-to-end voltage value is equal to or greater than the voltage threshold value, again controls the output unit 40 to switch the voltage value indicated by the switch signal to the high-level voltage value, acquires the end-to-end voltage value, controls the output unit 40 to switch the voltage value indicated by the switch signal to the low-level voltage value, and determines whether the end-to-end voltage value is equal to or greater than the voltage threshold value. In the case where the number of times that the control unit 30 successively determines that the end-to-end voltage value is equal to or greater than the voltage threshold value, that is, the voltage anomaly frequency, is equal to or greater than the reference frequency, the switch protection processing is ended in a state where the voltage values respectively indicated by the switch signal and the permission signal are being held at the low-level voltage value, assuming that the switch current value will not return to an appropriate value. Thereafter, the drive circuit 22 fixes the semiconductor switch 20 at OFF, without the control unit 30 resuming the switch protection processing.

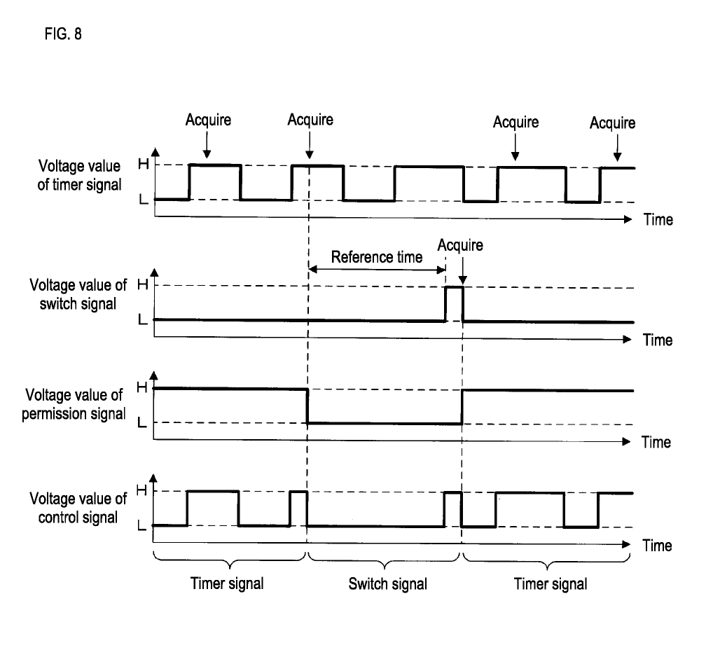

FIG. 8 is another illustrative diagram of operations of the power supply control device 10. Transition of the voltage values respectively indicated by the timer signal, the switch signal, the permission signal and the control signal is shown in FIG. 8, similarly to FIG. 7. In FIG. 8 also, “H” indicates the high-level voltage value and “L” indicates the low-level voltage value. Time is shown on the horizontal axis.

Note that, in FIG. 8 also, similarly to FIG. 4, the voltage value of the timer signal in the period during which the permission signal indicates the low-level voltage value is the voltage value of a timer signal that is generated in the case where the permission signal is assumed to indicate the high-level voltage value.

Hereinafter, similarly to the description of FIG. 7, it is assumed that the switch current value is less than the reference current value, and that the output unit 38 is outputting the high-level voltage value.

Similarly to the description of FIG. 7, the switch signal indicates the low-level voltage value, and the semiconductor switch 20 is OFF, from when the control unit 30 determines that the end-to-end voltage value of the resistor R1 is equal to or greater than the voltage threshold value until the reference time elapses. In the case where the reference time has elapsed, the voltage value indicated by the switch signal is switched from the low-level voltage value to the high-level voltage value, and the control unit 30 acquires the end-to-end voltage value of the resistor R1, and again switches the voltage value indicated by the switch signal from the high-level voltage value to the low-level voltage value. The control unit 30 then again determines whether the end-to-end voltage value is equal to or greater than the voltage threshold value.

Here, the control unit 30, in the case where it is determined that the end-to-end voltage value is less than the voltage threshold value, that is, that the switch current value is less than the current threshold value, instructs the output unit 39 to switch the voltage value indicated by the permission signal from the low-level voltage value to the high-level voltage value, assuming that the switch current value is appropriate. The signal that the output circuit 42 is outputting to the AND circuit 43 thereby switches from the switch signal to the timer signal, and the AND circuit 43 outputs a timer signal generated based on the master signal and the slave signal to the drive circuit 22 as the control signal. The drive circuit 22 repeatedly switches the semiconductor switch 20 to ON and OFF alternately, based on the voltage value indicated by the timer signal.

Thereafter, because the permission signal is indicating the high-level voltage value, the switch protection processing is started, in the case where the voltage value indicated by the timer signal switches from the low-level voltage value to the high-level voltage value.

Note that the control unit 30 returns the voltage anomaly frequency to zero, in the case where it is determined that the end-to-end voltage value is less than the voltage threshold value.

With the power supply control device 10 constituted as described above, in the case where it is determined that the switch current value is equal to or greater than the current threshold value by the control unit 30, the output circuit 42 outputs the switch signal, and the drive circuit 22 switches the semiconductor switch 20 to ON or OFF based on the voltage value indicated by the switch signal. Thus, the control unit 30, in the case where it is determined that the switch current value is equal to or greater than the current threshold value, is able to switch the semiconductor switch 20 to ON or OFF independently of the position of a starting point in time of the cycle of the timer signal, by controlling the output unit 40 to switch the instruction of the switch signal.

Also, the drive circuit 22, in the case where the end-to-end voltage value of the resistor R1 is equal to or greater than the reference voltage value, that is, in the case where the switch current value is equal to or greater than the reference current value, switches the semiconductor switch 20 to OFF independently of the control signal, that is, the signal being output by the output circuit 42. The reference current value is a current value at which the semiconductor switch 20 is likely to immediately fail, for example. Because the semiconductor switch 20 is immediately switched to OFF in the case where the switch current value becomes equal to or greater than the reference current value, the semiconductor switch 20 is protected.

### Second Embodiment

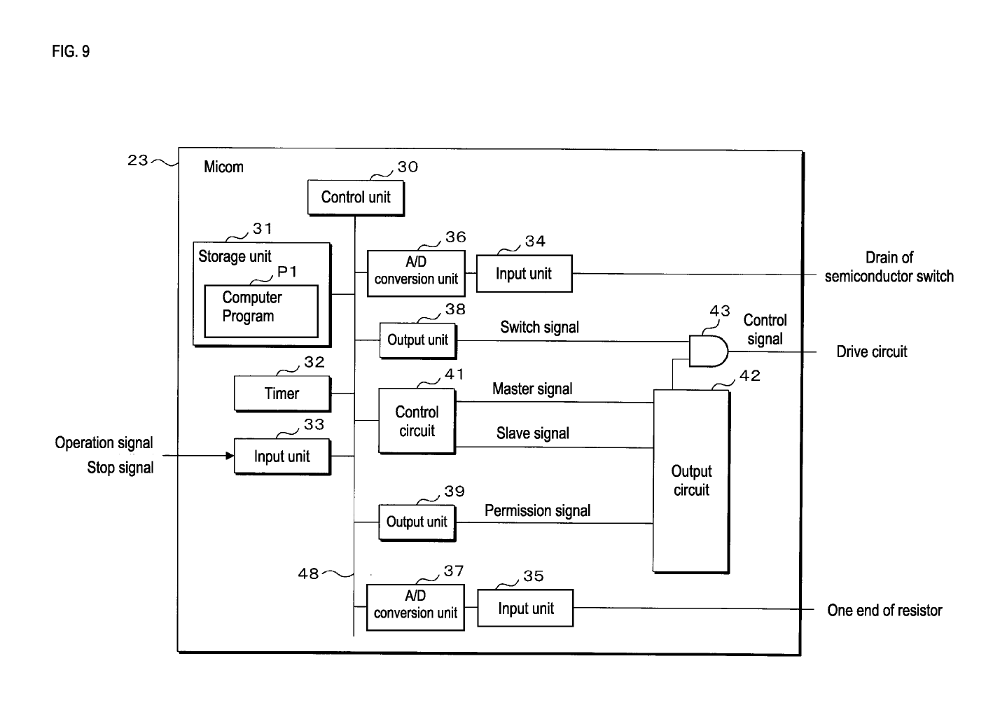

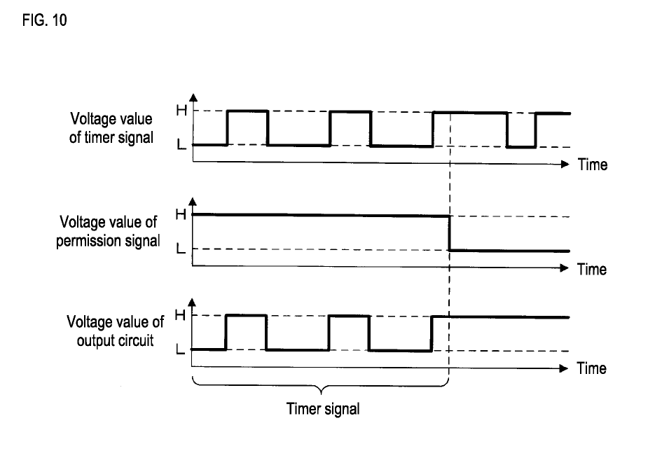

FIG. 9 is a block diagram showing the configuration of a principal part of the micom 23 in a second embodiment.

Hereinafter, differences from the first embodiment will be described with regard to the second embodiment. Since the configuration other than that which will be described later is in common with the first embodiment, the same reference signs as the first embodiment are given to constituent units that are in common with the first embodiment, and description thereof will be omitted.

The micom 23 in the second embodiment has all of the constituent units included in the micom 23 in the first embodiment except for the output unit 40.

In the second embodiment, the output unit 38 outputs the switch signal. The control unit 30 instructs the output unit 38 to switch the voltage value indicated by the switch signal to the high-level voltage value or the low-level voltage value. In the second embodiment, the output unit 38 functions as the switch signal output unit.

FIG. 10 is an illustrative diagram of operations of the output circuit 42. Transition of the voltage values respectively indicated by the timer signal and the permission signal and transition of the voltage value that the output circuit 42 outputs to the AND circuit 43 are shown in FIG. 10, similarly to FIG. 4. In FIG. 10 also, “H” indicates the high-level voltage value and “L” indicates the low-level voltage value. Time is shown on the horizontal axis.

Note that, in FIG. 10 also, similarly to FIG. 4, the voltage value of the timer signal in the period during which the permission signal indicates the low-level voltage value is the voltage value of a timer signal that is generated in the case where the permission signal is assumed to indicate the high-level voltage value.

The output circuit 42, in the case where the permission signal indicates the high-level voltage value, outputs a timer signal generated based on the master signal and the slave signal to the AND circuit 43, similarly to the first embodiment. The output circuit 42, in the case where the permission signal indicates the low-level voltage value, outputs the high-level voltage value to the AND circuit 43, without generating the timer signal.

The switch signal is input from the output unit 38 to one of the input ends of the AND circuit 43. The timer signal or the high-level voltage value is input from the output circuit 42 to the other input end of the AND circuit 43.

In the case where the switch signal indicates the high-level voltage value, the AND circuit 43 outputs the timer signal or high-level voltage value output by the output circuit 42 to the drive circuit 22. Here, in the case where the output circuit 42 is outputting the timer signal, the drive circuit 22 switches the semiconductor switch 20 to ON or OFF based on the voltage value indicated by the timer signal output by the AND circuit 43. In the case where the switch signal indicates the low-level voltage value, the AND circuit 43 outputs the low-level voltage value to the drive circuit 22, independently of the voltage value being output by the output circuit 42, and the drive circuit 22 keeps the semiconductor switch 20 switched to OFF.

In the case where the output circuit 42 is outputting the high-level voltage value, the AND circuit 43 outputs the switch signal to the drive circuit 22, and the drive circuit 22 switches the semiconductor switch 20 to ON or OFF based on the voltage value indicated by the switch signal output by the AND circuit 43.

In the power supply start processing, the control unit 30 instructs the output unit 38 to switch the voltage value indicated by the switch signal to the high-level voltage value, and instructs the output unit 39 to switch the voltage value indicated by the permission signal to the high-level voltage value. The drive circuit 22 thereby repeatedly switches the semiconductor switch 20 to ON and OFF alternately, based on the voltage value indicated by the timer signal. As a result, power supply to the load 12 is started, and the load 12 operates. The control unit 30, in the case of starting power supply to the load 12, instructs the control circuit 41 to gradually increase the duty of the timer signal from zero, similarly to the first embodiment. The control unit 30 ends the power supply start processing, in the case where the duty of the timer signal reaches a predetermined value, for example.

In the power supply end processing, the control unit 30 instructs the output unit 38 to switch the voltage value indicated by the switch signal to the low-level voltage value. The AND circuit 43 thereby continues to output the low-level voltage value, and the drive circuit 22 holds the semiconductor switch 20 at OFF. The control unit 30 ends the power supply end processing, after instructing the output unit 38 to switch the voltage value indicated by the switch signal to the low-level voltage value.

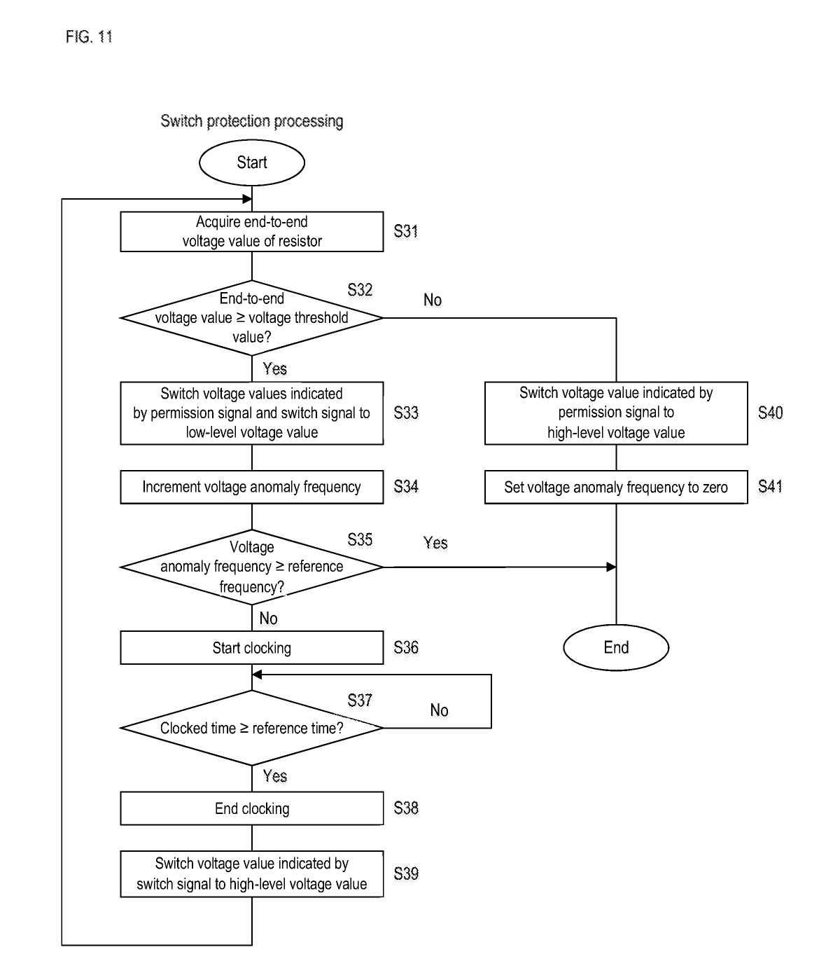

FIG. 11 is a flowchart showing a procedure of the switch protection processing. The control unit 30 executes the switch protection processing at a similar timing to the first embodiment. At the point in time at which the switch protection processing is started, the permission signal and the switch signal indicate the high-level voltage value, and the AND circuit 43 is outputting a timer signal generated based on the master signal and the slave signal to the drive circuit 22. The drive circuit 22 repeatedly switches the semiconductor switch 20 to ON and OFF alternately, based on the voltage value indicated by the timer signal.

Steps S31, S32, S34 to S41 of the switch protection processing in the second embodiment are respectively similar to step S11, S13, S15 to S22 of the switch protection processing in the first embodiment. Thus, detailed description of step S31, S32, S34 to S41 will be omitted.

In the switch protection processing, the control unit 30 executes step S32, after executing step S31. The control unit 30, in the case where it is determined that the end-to-end voltage value of the resistor R1 is equal to or greater than the voltage threshold value, that is, that the switch current value is equal to or greater than the current threshold value (S32: YES), instructs the output units 39 and 38 to respectively switch the voltage values indicated by the permission signal and the switch signal to the low-level voltage value (step S33). Since the permission signal indicates the low-level voltage value, the output circuit 42 outputs the high-level voltage value to the AND circuit 43. As a result, the AND circuit 43 outputs the switch signal to the drive circuit 22 as the control signal. Here, since the switch signal is the low-level voltage value, the drive circuit 22 switches the semiconductor switch 20 to OFF.

The control unit 30 executes step S34, after executing step S33. In step S39, the control unit 30 instructs the output unit 38 to switch the voltage value indicated by the switch signal to the high-level voltage value. At the point in time at which step S39 is executed, the output circuit 42 is outputting the high-level voltage value to the AND circuit 43. Thus, in the case where step S39 is executed, the drive circuit 22 switches the semiconductor switch 20 to ON. Thereafter, the control unit 30 sequentially executes step S31 and S32.

At the point in time at which the control unit 30 executes step S32, the switch signal indicates the high-level voltage value. Thus, in step S40, the voltage value indicated by the permission signal is switched to the high-level voltage value, in a state where the switch signal indicates the high-level voltage value. The output circuit 42 thereby outputs a timer signal generated based on the master signal and the slave signal to the AND circuit 43, and the AND circuit 43 outputs the timer signal to the drive circuit 22 as the control signal.

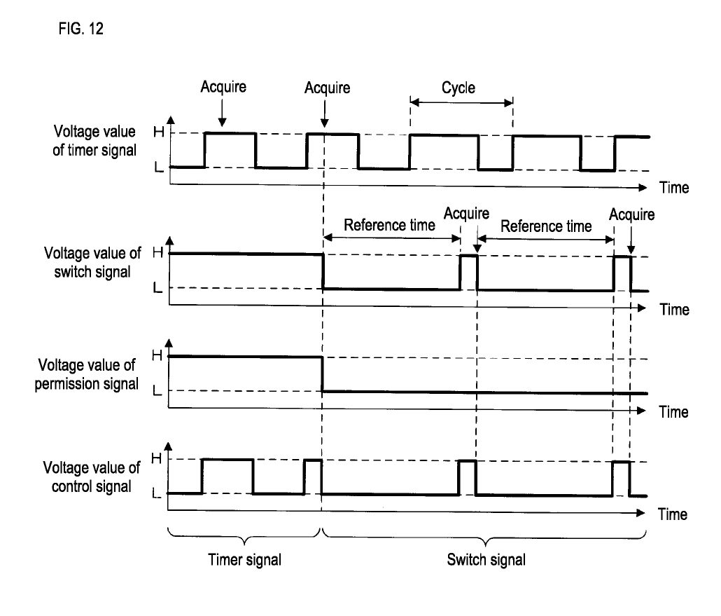

FIG. 12 is an illustrative diagram of operations of the power supply control device 10. Transition of the voltage values respectively indicated by the timer signal, the switch signal, the permission signal and the control signal is shown in FIG. 12, similarly to FIG. 7. In FIG. 12 also, “H” indicates the high-level voltage value and “L” indicates the low-level voltage value. Time is shown on the horizontal axis.

Note that, in FIG. 12 also, similarly to FIG. 4, the voltage value of the timer signal in the period during which the permission signal indicates the low-level voltage value is the voltage value of a timer signal that is generated in the case where the permission signal is assumed to indicate the high-level voltage value.

Hereinafter, it is assumed that the switch current value is less than the reference current value. As aforementioned, in the case where the operation signal is input to the input unit 33, the voltage values indicated by the permission signal and the switch signal are switched to the high-level voltage value.

In the case where the permission signal and the switch signal indicate the high-level voltage value, the output circuit 42 outputs a timer signal generated based on the master signal and the slave signal to the AND circuit 43, and the AND circuit 43 outputs the timer signal to the drive circuit 22 as the control signal. Thus, the drive circuit 22 repeatedly switches the semiconductor switch 20 to ON and OFF alternately, based on the voltage value indicated by the timer signal.

In the case where the voltage value indicated by the timer signal switches from the low-level voltage value to the high-level voltage value in a state where the permission signal indicates the high-level voltage value, the control unit 30 starts the switch protection processing, similarly to the first embodiment. In the switch protection processing, the control unit 30 acquires the end-to-end voltage value of the resistor R1 from the A/D conversion unit 37, and determines whether the end-to-end voltage value is equal to or greater than the voltage threshold value. The time from when the switch protection processing is started until when the end-to-end voltage value is acquired is shorter than the minimum ON time capable of being adjusted to with the timer signal.

The control unit 30, in the case where it is determined that the end-to-end voltage value of the resistor R1 is less than the voltage threshold value, ends the switch protection processing in a state where the voltage values respectively indicated by the switch signal and the permission signal are maintained at the high-level voltage value. Thereafter, in the case where the voltage value indicated by the timer signal switches from the low-level voltage value to the high-level voltage value, the control unit 30 again starts the switch protection processing, acquires the end-to-end voltage value, and determines whether the end-to-end voltage value is equal to or greater than the voltage threshold value.

The control unit 30, in the case where it is determined that the end-to-end voltage value of the resistor R1 is equal to or greater than the voltage threshold value, instructs the output units 38 and 39 to respectively switch the voltage values indicated by the permission signal and the switch signal to the low-level voltage value. The output circuit 42 thereby outputs the high-level voltage value to the AND circuit 43, and the AND circuit 43 outputs the switch signal as the control signal. At this time, the switch signal is indicating the low-level voltage value, and thus the drive circuit 22 switches the semiconductor switch 20 to OFF.

The control unit 30, in the case where the reference time has elapsed from when it is determined that the end-to-end voltage value is equal to or greater than the voltage threshold value, instructs the output unit 38 to switch the voltage value indicated by the switch signal from the low-level voltage value to the high-level voltage value. The drive circuit 22 thereby switches the semiconductor switch 20 to ON. Thereafter, the control unit 30 acquires the end-to-end voltage value of the resistor R1 from the A/D conversion unit 37, and again determines whether the end-to-end voltage value of the resistor R1 is equal to or greater than the voltage threshold value.

The control unit 30, in the case where it is determined that the end-to-end voltage value of the resistor R1 is equal to or greater than the voltage threshold value, that is, that the switch current value is equal to or greater than the current threshold value, controls the output unit 38 to switch the switch signal to the low-level voltage value, assuming that the switch current value is still not appropriate. The drive circuit 22 again holds OFF of the semiconductor switch 20 for the reference time. The control unit 30, in the case where the reference time has elapsed from when it is determined that the end-to-end voltage value is equal to or greater than the voltage threshold value, again controls the output unit 38 to switch the voltage value indicated by the switch signal to the high-level voltage value, acquires the end-to-end voltage value, and determines whether the end-to-end voltage value is equal to or greater than the voltage threshold value. In the case where the number of times that the control unit 30 successively determines that the end-to-end voltage value is equal to or greater than the voltage threshold value, that is, the voltage anomaly frequency, is equal to or greater than the reference frequency, the switch protection processing is ended in a state where the voltage values respectively indicated by the switch signal and the permission signal are held at the low-level voltage value, assuming that the switch current value will not return to an appropriate value. Thereafter, the drive circuit 22 fixes the semiconductor switch 20 at OFF, without the control unit 30 resuming the switch protection processing.

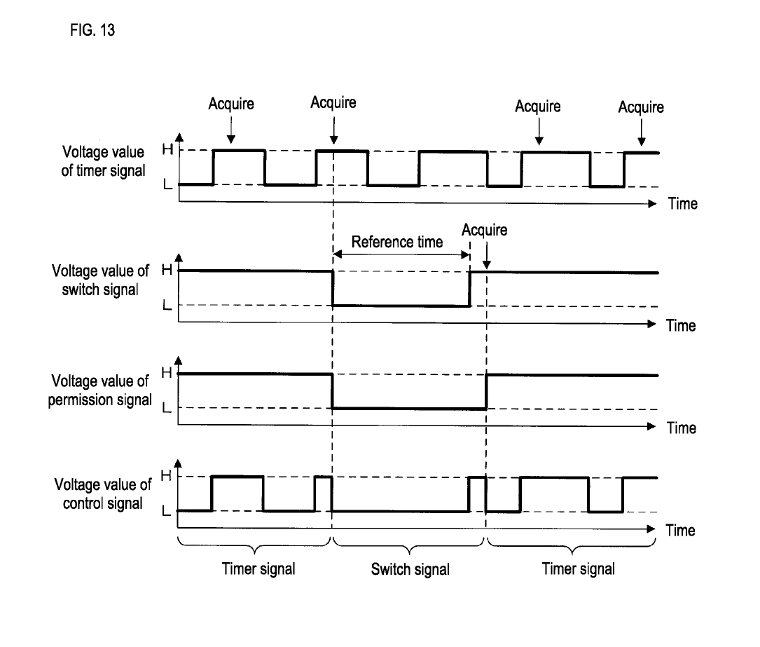

FIG. 13 is another illustrative diagram of operations of the power supply control device 10. Transition of the voltage values respectively indicated by the timer signal, the switch signal, the permission signal and the control signal is shown in FIG. 13, similarly to FIG. 12. In FIG. 13 also, “H” indicates the high-level voltage value and “L” indicates the low-level voltage value. Time is shown on the horizontal axis.

Note that, in FIG. 13 also, similarly to FIG. 4, the voltage value of the timer signal in the period during which the permission signal indicates the low-level voltage value is the voltage value of a timer signal that is generated in the case where the permission signal is assumed to indicate the high-level voltage value.

Hereinafter, it is assumed that the switch current value is less than the reference current value, similarly to the description of FIG. 12.

Similarly to the description of FIG. 12, the permission signal and the switch signal indicate the low-level voltage value and the semiconductor switch 20 is OFF, until the reference time elapses from when the control unit 30 determines that the end-to-end voltage value of the resistor R1 is equal to or greater than the voltage threshold value. In the case where the reference time has elapsed, the voltage value indicated by the switch signal is switched from the low-level voltage value to the high-level voltage value, and the control unit 30 acquires the end-to-end voltage value of the resistor R1, and again determines whether the end-to-end voltage value is equal to or greater than the voltage threshold value.

Here, the control unit 30, in the case where it is determined that the end-to-end voltage value is less than the voltage threshold value, that is, that the switch current value is less than the current threshold value, instructs the output unit 39 to switch the voltage value indicated by the permission signal from the low-level voltage value to the high-level voltage value, in a state where the voltage value indicated by the switch signal is maintained at the high-level voltage value, assuming that the switch current value is appropriate. The signal that the output circuit 42 is outputting to the AND circuit 43 thereby switches from the switch signal to the timer signal, and the AND circuit 43 outputs a timer signal generated based on the master signal and the slave signal to the drive circuit 22 as the control signal. The drive circuit 22 repeatedly switches the semiconductor switch 20 to ON and OFF alternately, based on the voltage value indicated by the timer signal.

Thereafter, the permission signal indicates the high-level voltage value, and thus the switch protection processing is started, in the case where the voltage value indicated by the timer signal switches from the low-level voltage value to the high-level voltage value.

The power source system 1 and the power supply control device 10 in the second embodiment achieve similar effects to the first embodiment. With the power supply control device 10 in the second embodiment, as described above, the AND circuit 43, in the case where it is determined by the control unit 30 that the switch current value is less than the current threshold value, outputs the timer signal output by the control circuit 41 to the drive circuit 22, and, in the case where it is determined by the control unit 30 that the switch current value is equal to or greater than the current threshold value, outputs the switch signal output by the output unit 38 to the drive circuit 22. Also, the AND circuit 43, in the case where it is determined by the control unit 30 that the switch current value is equal to or greater than the current threshold value, outputs a switch signal instructing OFF of the semiconductor switch 20 to the drive circuit 22, and, in the case where the reference time has elapsed from when it is determined by the control unit 30 that the switch current value is equal to or greater than the current threshold value, outputs a switch signal instructing ON of the semiconductor switch 20. Accordingly, the AND circuit 43 functions as the signal output device.

Note that, in the first and second embodiments, with the timer signal, switching from the low-level voltage value to the high-level voltage value is periodically performed, and the duty of the timer signal is changed, by adjusting the switching timing from the high-level voltage value to the low-level voltage value. However, with the timer signal, switching from the high-level voltage value to the low-level voltage value may be periodically performed, and the duty of the timer signal may be changed, by adjusting the switching timing from the low-level voltage value to the high-level voltage value.

In this case, acquisition of the end-to-end voltage value of the resistor R1 is performed immediately before the voltage value indicated by the timer signal switches from the high-level voltage value to the low-level voltage value. The time from the point in time of acquisition time of the end-to-end voltage value until when the voltage value indicated by the timer signal switches from the high-level voltage value to the low-level voltage value is shorter than the minimum ON time capable of being adjusted to with the timer signal.

Also, the master counter value and the slave counter value may each be incremented by 1, whenever a fixed time elapses. In this case, the master counter value is changed from the first integer value to zero, when the fixed time has elapsed from when the master counter value becomes the first integer value, and the slave counter value is changed from the second integer value to zero, when the fixed time has elapsed from when the slave counter value becomes the second integer value. The slave counter value is maintained at zero from when the slave counter value is changed to zero until when the master counter value is changed to zero. The slave counter value is changed to 1, in the case where the master counter value is changed to zero. Thereafter, the slave counter value is incremented by 1, whenever the fixed time elapses. The voltage value indicated by the master signal switches from the low-level voltage value to the high-level voltage value in the case where the master counter value is changed from the first integer value to zero. The voltage value indicated by the slave signal switches from the low-level voltage value to the high-level voltage value in the case where the slave counter value is changed from the second integer value to zero. The voltage values indicated by the master signal and the slave signal return to the low-level voltage value immediately after switching to the high-level voltage value.

The semiconductor switch 20 is not limited to an N-channel FET, and may be a P-channel FET or a bipolar transistor.

The disclosed first and second embodiments are considered in all respects to be illustrative and not restrictive. The scope of the disclosure is indicated by the claims rather than by the abovementioned content, and all changes that come within the meaning and range of equivalency of the claims are intended to be encompassed therein.

1. A power supply control device comprising:
a semiconductor switch;
a switch signal output unit configured to output a switch signal instructing OFF or ON of the semiconductor switch;
a determination unit configured to determine whether a value of a switch current that flows via the semiconductor switch is equal to or greater than a current threshold value;
a signal output device configured to output a PWM signal, in a case where the determination unit determines that the switch current value is less than the current threshold value, and to output the switch signal output by the switch signal output unit, in a case where the determination unit determines that the switch current value is equal to or greater than the current threshold value; and
a switching unit configured to switch the semiconductor switch to ON or OFF, based on the PWM signal or switch signal output by the signal output device,
wherein the signal output device:
outputs a switch signal instructing OFF of the semiconductor switch, in a case where the determination unit determines that the switch current value is equal to or greater than the current threshold value, and
outputs a switch signal instructing ON of the semiconductor switch, in a case where a predetermined time has elapsed from when the determination unit determines that the switch current value is equal to or greater than the current threshold value, and
the determination unit again determines whether the switch current value is equal to or greater than the current threshold value, after the signal output device outputs the switch signal instructing ON of the semiconductor switch.

2. (canceled)

3. The power supply control device according to claim 1,
wherein the switching unit fixes the semiconductor switch at OFF, in a case where the determination unit successively determines that the switch current value is equal to or greater than the current threshold value a predetermined number of times or more.

4. The power supply control device according to claim 1,
wherein the switching unit switches the semiconductor switch to OFF independently of the signal being output by the signal output device, in a case where the switch current value becomes equal to or greater than a predetermined current value, and
the current threshold value is less than the predetermined current value.

5. The power supply control device according to claim 3,
wherein the switching unit switches the semiconductor switch to OFF independently of the signal being output by the signal output device, in a case where the switch current value becomes equal to or greater than a predetermined current value, and
the current threshold value is less than the predetermined current value.
